(19) United States
(12) Patent Application Publication
(10) Pub. No.: US 2009/0300313 A1
(43) Pub. Date: Dec. 3, 2009

(54) MEMORY CLEARING APPARATUS FOR ZERO CLEARING

(75) Inventor: Tsunehisa Doi, Kawasaki (JP)

Correspondence Address: GREER, BURNS & CRAIN, 300 S WACKER DR, 25TH FLOOR, CHICAGO, IL, 60606, US

(73) Assignee: FUJITSU LIMITED, Kawasaki-shi (JP)

(21) Appl. No.: 12/371,844

(22) Filed: Feb. 16, 2009

(30) Foreign Application Priority Data
May 30, 2008 (JP) 2008-142286

(51) Int. Cl. G06F 12/00; G11C 7/00

(52) U.S. Cl. 711/166; 365/218; 711/E12.001

(57) ABSTRACT

A memory clear apparatus includes a processor that issues a memory clear request including a zero clear target area on a memory area and a zero clear target size, and a memory clearing circuit that receives the memory clear request from the processor, performs zero clearing on the zero clear target area based on the memory clear request, and transmits a memory clear completion notification to the processor.

### CROSS-REFERENCE TO RELATED APPLICATION

This application is based upon and claims the benefit of priority of the prior Japanese Patent Application No. 2008-142286, filed on May 30, 2008, the entire contents of which are incorporated herein by reference.

### FIELD

The present invention relates to a memory clearing apparatus for zero clearing.

### BACKGROUND

Up to now, when it is necessary to reallocate a memory area in a computing system, in order to refresh the memory area, the memory area is zero-cleared in response to a normal store instruction from a processor such as a CPU (for example, Japanese Laid-open Patent Publication No. 60-197994) zero clearing is performed by a direct memory access (DMA) controller(for example, Japanese Laid-open Patent Publication No. 60-197995), or zero clearing is performed by a provided memory clearing circuit (for example, Japanese Laid-open Patent Publication No. 01-94594).

However, in a zero clearing method according to a conventional technology, a time length required for zero clearing depends on a throughput performance of memory access. Therefore, there is a case where the zero clearing takes a long time.

Even in the case of the zero clearing using the memory clearing circuit, it is necessary to perform cache invalidation processing by software. Therefore, there is a case where the zero clearing takes a long time.

Therefore, in some conditions, a virtual machine (VM) or an operating system (OS) cannot sufficiently deal with a case in which zero clearing for the reuse of page or high-speed memory clearing (zero clearing) such as memory clearing in a hardware simulation is required.

### SUMMARY

One of aspects of a memory clearing apparatus includes: a processor that issues a memory clear request including a zero clear target area on a memory area and a zero clear target size; and

a memory clearing circuit that receives the memory clear request from the processor, performs zero clearing on the zero clear target area based on the memory clear request, and transmits a memory clear completion notification corresponding to the memory clear request to the processor.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF THE DRAWINGS

FIG. 1 is an explanatory diagram illustrating a memory clearing apparatus;

FIG. 2 is an operational explanatory diagram illustrating the memory clearing apparatus (structural example of Specific Example 1);

FIG. 3 illustrates a structural example of Specific Example 2 of the memory clearing apparatus;

FIG. 4 illustrates a structural example of Specific Example 3 of the memory clearing apparatus;

FIG. 5 illustrates a structural example of Specific Example 4 of the memory clearing apparatus;

FIG. 6 illustrates a structural example of Specific Example 5 of the memory clearing mechanism; and

FIG. 7 illustrates a structural example of Specific Example 5 of the memory clearing mechanism.

### DESCRIPTION OF EMBODIMENTS

Hereinafter, an embodiment is described with reference to the drawings. The following structures of the embodiment are examples.

<Method of Solving Problem>

A memory clearing apparatus according to the embodiment includes a zero clearing circuit (memory clearing circuit) provided on a memory device side in order to shorten a time length required for zero clearing. For example, the zero clearing circuit designates a plurality of memory cells included in a dynamic random access memory (DRAM) at the same time to simultaneously discharge charges from the respective memory cells, thereby realizing zero clearing. The zero clearing circuit executes zero clearing on a corresponding memory area based on designated addresses and a signal indicating a size of the memory area to be cleared (size signal).

The addresses and the size signal are issued from a processor such as a central processing unit (CPU). Therefore, a zero clear specific instruction can be installed. That is, a structure can be applied in which the processor issues the zero clear specific instruction including the addresses and the size signal.

For example, a configuration can be applied in which the designated size for the zero clearing is assumed to be the power of 2 and the addresses are matched with the designated size. A configuration capable of determining a designated memory area by a simple decoder can be applied in the zero clearing circuit.

The memory clearing apparatus including the above-mentioned zero clearing circuit can be applied to a system which requires zero clearing of a predetermined memory area, such as entire page clearing at the time of the reuse of page.

<Outline of Memory Clearing Apparatus>

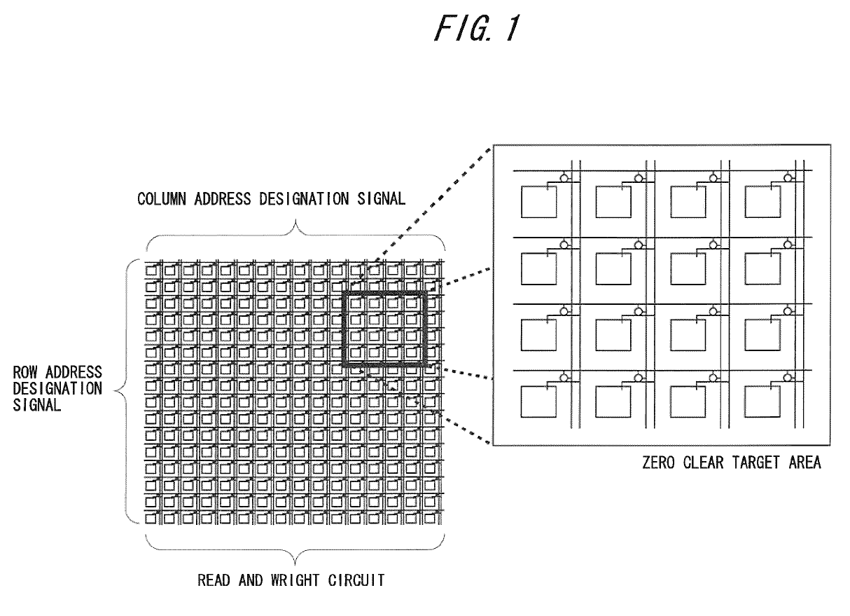

FIG. 1 is an explanatory diagram illustrating the memory clearing apparatus. FIG. 1 illustrates a memory area of, for example, a DRAM, which can be applied to the memory clearing apparatus. The memory area includes a plurality of memory cells arranged in predetermined rows and columns and is provided with a read and write circuit for each of the memory cells. Each of the memory cells is connected with a row address designation signal line and a column address designation signal line. The read and write circuit can detect signals inputted to the row and column address designation signal lines to specify a memory cell to be controlled.

In a normal memory address designation circuit, only one of the row signal lines and only one of the column signal lines are designated based on a row address designation signal and a column address designation signal, and a value (0 or 1) of a memory cell corresponding to the row and the column is read. At the time of zero clearing, zero is written into the memory cell.

In contrast to the normal memory address designation circuit, in the zero clearing circuit according to the embodiment, a plurality of address signal lines corresponding to rows and columns are simultaneously designated, whereby a zero clear target area including the plurality of rows and the plurality of columns is designated. The zero clearing circuit zero-clears the contents of the respective memory cells included in the designated area.

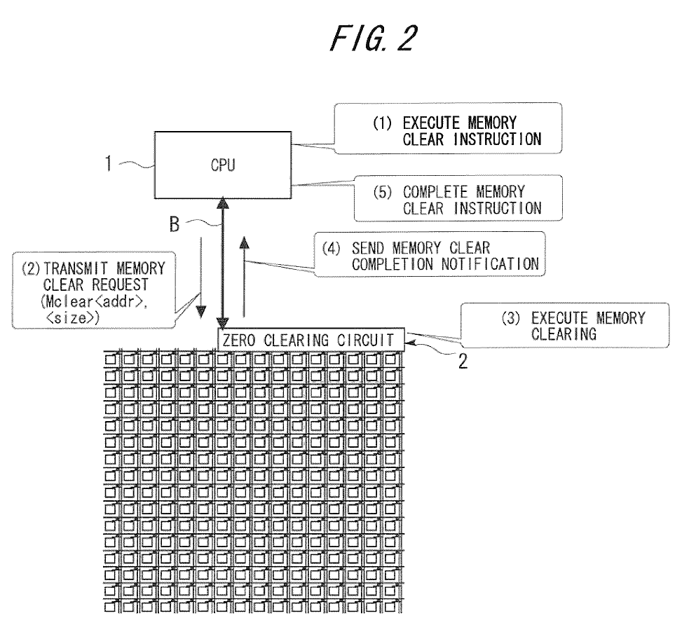

FIG. 2 is an explanatory diagram illustrating a flow of execution of a memory clear instruction. In the memory clearing apparatus, a processor (CPU) 1 starts to execute the memory clear instruction ((1) of FIG. 2). That is, the CPU 1 issues the zero clear instruction to a zero clearing circuit 2. For example, the zero clear instruction may be a special instruction for zero clearing. The zero clearing circuit 2 is a controller which interprets the memory clear instruction (memory clear request) from the CPU 1 with respect to the memory area as illustrated in FIG. 1 and executes zero clearing corresponding to the memory clear instruction.

At this time, a memory clear instruction “Mclear <addr>, <size>” is issued as the zero clear special instruction from the CPU 1. The memory clear instruction includes: addresses (column addresses and row addresses) “<addr>” for designating the zero clear target area; and a zero clear target area size “<size>”.

When the memory clear instruction is executed by the CPU 1, a bus transaction for memory clearing occurs. Then, the CPU 1 transmits the memory clear request including the memory clear instruction to the zero clearing circuit through a bus B ((2) of FIG. 2).

In the zero clearing circuit 2, the zero clear target area is specified based on the memory clear instruction. For example, the charges are discharged from the respective memory cells included in the area to thereby execute the memory clearing (zero clearing) of the zero clear target area ((3) of FIG. 2).

When the memory clearing is completed, the zero clearing circuit 2 generates a memory clear completion notification and sends the memory clear completion notification to the CPU 1 through the bus B ((4) of FIG. 2). In this way, when the memory clearing is completed on the zero clearing circuit 2 side, the memory clear completion notification reaches, as the bus transaction, the CPU 1. Then, the CPU 1 ends the memory clear instruction ((5) of FIG. 2). At this time, a block of the memory clear instruction is released.

According to the configuration and the operation as described above, the zero cleaning of the predetermined area can be realized at higher speed than in the case where the successive write processing of zero “0” is executed by the processor or the DMA. The memory area is cleared at high speed, and hence the page clearing for the reuse of page is increased in speed to shorten a time length to the reuse. Processing requiring zero clearing of a data area having a certain size can be increased in speed.

### SPECIFIC EXAMPLE 1

Next, Specific Example 1 of the memory clearing apparatus described with reference to FIGS. 1 and 2 is described. A memory clearing apparatus of Specific Example 1 is equal in configuration to that of FIG. 2, and includes: the zero clearing circuit (memory clearing circuit) 2 which executes the zero clearing on the memory area including the zero clear target area; and the processor (CPU) 1 which is connected with the zero clearing circuit 2 through the bus B and executes the memory clear instruction.

In Specific Example 1, once the CPU 1 starts to execute the memory clear instruction, the execution of other instructions is stopped until the memory clearing is completed (memory clear completion notification is received). The zero clearing circuit 2 performs the memory clearing (zero clearing) on a designated area of the memory area. That is, the zero clear target area to be zero-cleared by the zero clearing circuit 2 is predetermined. Alternatively, the zero clear target area (addresses and size) may be arbitrarily determined based on the memory clear instruction.

Bus signals for memory clearing are newly provided. For example, with respect to a message of each of “request” and “complete” in a split transaction recently often applied in this art, the memory clear request is mapped to “request” and the memory clear completion is mapped to “complete”.

When the configuration described above is applied to the memory clearing apparatus illustrated in FIGS. 1 and 2, the designated area can be conducted to high-speed zero clearing (memory clearing).

### SPECIFIC EXAMPLE 2

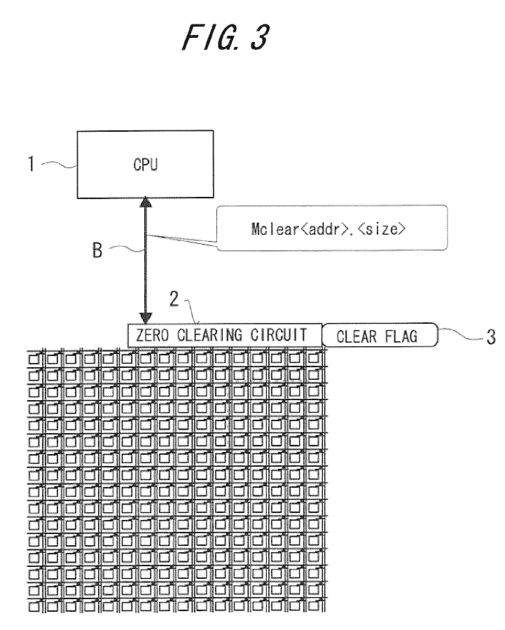

FIG. 3 illustrates a configuration example of Specific Example 2. In Specific Example 1, once the CPU 1 transmits the memory clear request, the execution of other instructions is stopped until the memory clear completion is received. In Specific Example 2, in addition to the configuration of Specific Example 1, as illustrated in FIG. 3, the zero clearing circuit 2 includes a clear flag 3 for each zero clear target area.

That is, upon receiving the memory clear request from the CPU 1, the zero clearing circuit 2 updates (sets ON “1” to) the clear flag 3 for the zero clear target area corresponding to the memory clear request and transmits the memory clear completion to the CPU 1. After that, the zero clearing circuit 2 performs the zero clearing on the zero clear target area whose clear flag 3 is ON.

Therefore, the memory clear instruction execution time (waiting time for the memory clear completion) of the CPU 1 is shortened. Thus, the CPU 1 can execute a next instruction in a short time after the memory clear request is transmitted.

### SPECIFIC EXAMPLE 3

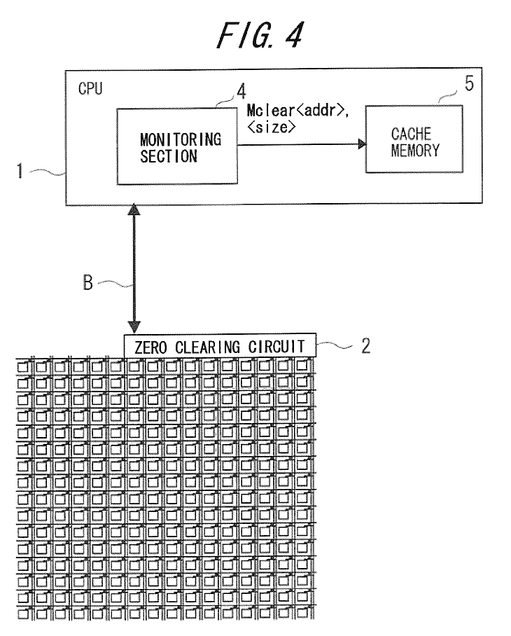

FIG. 4 illustrates a configuration example of Specific Example 3. In Specific Example 3, in addition to the configuration (FIG. 2) of Specific Example 1, a clear snoop function (monitoring section) 4 is provided in a cache controller of the CPU 1. The monitoring section 4 snoops a memory clear transaction (memory clear request or memory clear completion) flowing on the bus B to monitor the generation of the memory clear instruction, specifies the zero clear target area based on the memory clear request, and performs zero clearing on a corresponding area of a cache memory 5 included in the CPU 1.

According to Specific Example 3, the status of the cache memory 5 can be set to match with the memory area. In Specific Example 3, the cache controller (monitoring section 4) and the cache memory 5 are included in the CPU 1. However, at least one of the monitoring section 4 and the cache memory 5 may be provided outside the CPU 1.

### SPECIFIC EXAMPLE 4

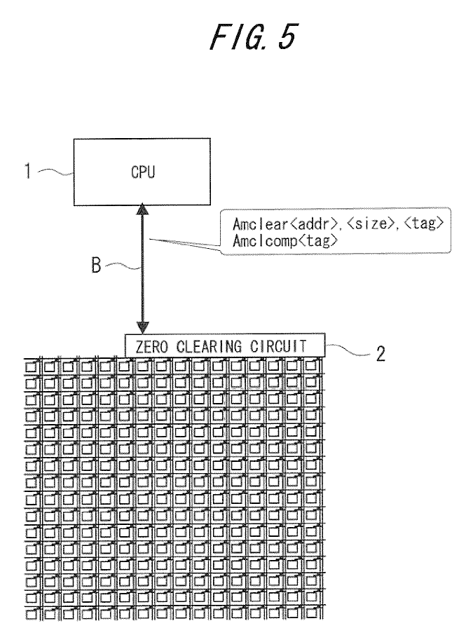

FIG. 5 illustrates a structural example of Specific Example 4. In Specific Example 4, in addition to the structure (FIG. 2) of Specific Example 1, or instead of the bus transaction (memory clear request or memory clear completion) described in Specific Example 1, an asynchronous instruction for memory clearing is applied.

In Specific Example 4, the CPU 1 can execute another instruction after the issue of the memory clear request and before the receipt of the memory clear completion corresponding to the memory clear request. In Specific Example 4, as illustrated in FIG. 5, a memory clear instruction “Amclear <addr>,<size>,<tag>” including a tag “<tag>” in addition to the address and the size is issued.

The tag is used as an instruction type identifier. The tag is added also to the memory clear completion notification. That is, the CPU 1 receives the memory clear completion “Amclcomp <tag>” having the tag from the zero clearing circuit 2.

The CPU 1 can discriminate the tag of the memory clear completion notification to discriminate the memory clear request corresponding to the memory clear completion, thereby recognizing the completion of processing corresponding to the request. According to Specific Example 4, the CPU 1 can successively issue memory clear requests for a plurality of zero clear target areas (for example, plurality of pages). Therefore, a large number of areas can be zero-cleared at high speed.

### SPECIFIC EXAMPLE 5

Next, a configuration described in Specific Example 3 for eliminating the cache mismatching is described in detail as Specific Example 5. The memory clearing apparatus is assumed to be used for page clearing in, for example, a virtual machine (VM) or an operating system. A zero clear target memory to be used for page clearing is a normal memory space. The normal memory space includes a cacheable area. When the cacheable area is subjected to zero clearing, it is necessary to inhibit the cache mismatching.

Therefore, in Specific Example 5, a function for treating the memory clear transaction as cache invalidation is introduced into the snoop function for cache.

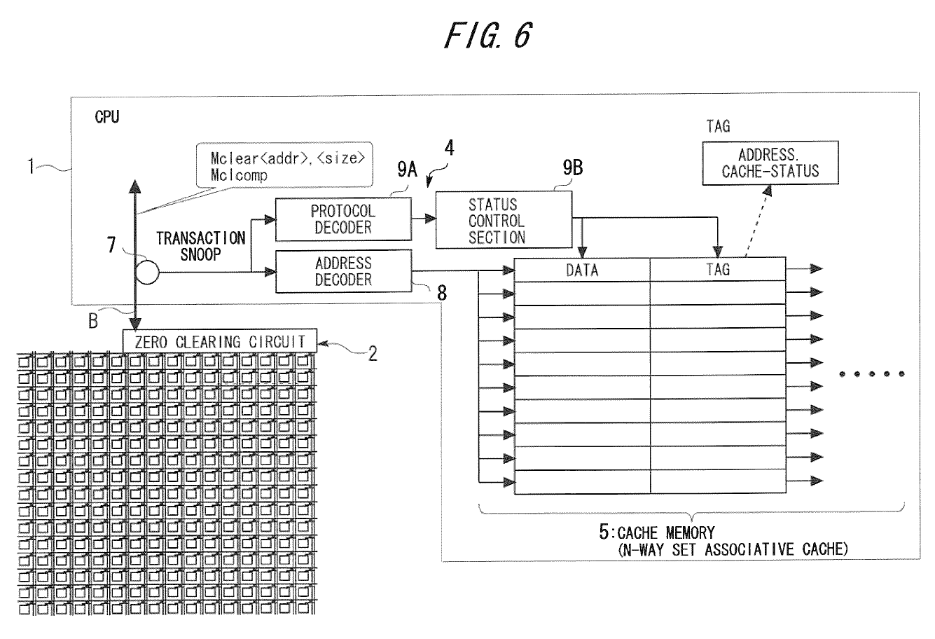

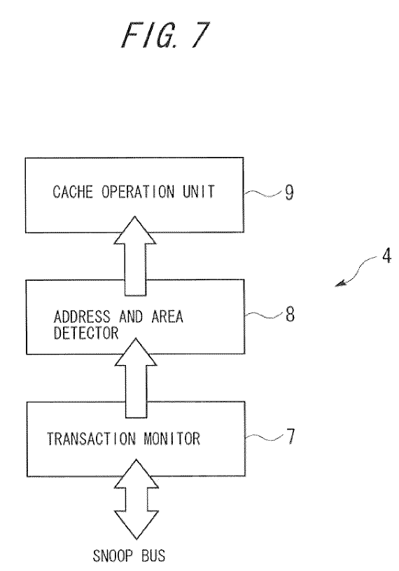

FIG. 6 illustrates a structural example of Specific Example 5. FIG. 7 illustrates a structural example of a monitoring section 4 (clear snoop section or cache control section). A configuration of Specific Example 5 is substantially equal to the structure (FIG. 3) of Specific Example 3. In FIGS. 6 and 7, the monitoring section (clear snoop section) 4 detects the memory clear request ((2) of FIG. 2) transmitted from the CPU 1 to serve as a transaction for invalidating a corresponding area on the cache memory 5. The corresponding area on the cache memory 5 corresponds to the zero clear target area on the memory.

In FIGS. 6 and 7, the monitoring section 4 includes: a transaction monitor 7 which snoops the memory clear transaction from the snoop bus (bus B); an address and area detector (address decoder) 8 which detects, from the memory clear request, a zero clear target address and a zero clear target area on the cache memory 5; and a cache operation section 9 (protocol decoder 9A and status control section 9B) which invalidates the address and the area which are detected by the address decoder 8.

FIG. 6 illustrates an N-way set associative cache as the cache memory 5. The cache memory 5 includes a plurality of ways. Each of the ways includes a table having a data area and a tag area. Each of the areas is associated with a next way. Cached data is stored in the data area. A data address on the memory area and a status on the cache are stored in the tag area.

When the monitoring section 4 snoops the memory clear request, the monitoring section 4 performs clearing on the cache memory 5 in parallel to the zero clearing performed by the zero clearing circuit 2.

The monitoring section 4 interprets the memory clear request as the invalidation. In the normal invalidation, only one cache line is subjected to the invalidation operation. In contrast to this, in this embodiment, all cache lines which correspond to the clear size and the clear addresses in the memory clear request are subjected to the invalidation operation.

In the normal cache snoop function, the cache operation is performed by a procedure called an MESI protocol. In the MESI protocol, the cache status is changed among four statuses including a status “Share (S)” indicating that data on the data area (cache) is shared with the memory area, a status “Exclusive (E)” indicating that the data on the data area is held on only the cache, a status “Modify (M)” indicating that data on the memory area is updated on only the cache, and a status “Invalidated (I)” indicating that the data on the data area is invalid.

The cache operation section 9 operates as follows. The protocol decider 9A interprets the memory transaction (memory clear request) as a status transition instruction in the MESI protocol. The status control section 9B controls the cache status of each tag area and changes, to the invalidation status “I”, the cache status (any one of S, E, and M) of a tag for a data area which corresponds to the address and the area which are detected by the address decoder 8. Therefore, cache data corresponding to the zero clear target area is invalidated. Thus, the cache mismatching is inhibited.

The configuration of Specific Examples 1 to 5 described above can be combined as appropriate.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment(s) of the present inventions have been described in detail, it should be understood that the various changes, substitutions, and alterations could be made hereto without departing from the spirit and scope of the invention.

What is claimed is:

1. A memory clearing apparatus, comprising:
a processor that issues a memory clear request including a zero clear target area on a memory area and a zero clear target size; and
a memory clearing circuit that receives the memory clear request from the processor, performs zero clearing on the zero clear target area based on the memory clear request, and transmits a memory clear completion notification corresponding to the memory clear request to the processor.

2. The memory clearing apparatus according to claim 1, further comprising a cache control section that detects the memory clear request, determines an area on a cache memory which corresponds to the zero clear target area, and invalidates data stored in the area on the cache memory.

3. A memory clearing method for a memory clearing apparatus, comprising:
issuing, by a processor, a memory clear request including a zero clear target area on a memory area and a zero clear target size;
receiving, by a memory clearing circuit, the memory clear request from the processor;
performing, by the memory clearing circuit, zero clearing on the zero clear target area based on the memory clear request; and
transmitting, by the memory clearing circuit, a memory clear completion notification corresponding to the memory clear request to the processor.
